(19) United States
(12) Patent Application Publication
(10) Pub. No.: US 2011/0212630 A1
(43) Pub. Date: Sep. 1, 2011

(54) METHOD FOR PREPARING A SELF-SUPPORTING CRYSTALLIZED SILICON THIN FILM

(75) Inventors: Jean-Paul Garandet, Grenoble (FR); Denis Camel, Chambery (FR); Béatrice Drevet, Grenoble (FR)

(73) Assignee: Commissariat A L'Energie Atomique et aux Energies Alternatives, Paris (FR)

(21) Appl. No.: 13/062,462

(22) PCT Filed: Sep. 3, 2009
(86) PCT No.: PCT/FR09/51667

§ 371 Date: May 9, 2011

(30) Foreign Application Priority Data
Sep. 5, 2008 (FR) 0855969

(51) Int. Cl. H01L 21/26; B32B 9/04; B29C 39/00; C30B 11/02

(52) U.S. Cl. 438/795; 428/446; 264/266; 117/81; 257/E21.328

(57) ABSTRACT

The invention relates to a method for preparing a self-supporting crystallized silicon thin film having a grain size of more than 1 mm. The invention also relates to the use of said method for preparing self-supporting silicon bands and to the bands thus obtained.

The invention relates to a recrystallization process for obtaining self-supporting silicon ribbons with a “coarse-grain” crystallographic structure, these ribbons being particularly advantageous for the production of photovoltaic cells.

Photovoltaic cells are essentially manufactured from mono- or polycrystalline silicon.

This silicon is generally obtained by solidifying silicon cylinders, starting with a liquid silicon bath. The cylinder is then cut into wafers that are used for manufacturing the cells.

To avoid loss of material generated during the sawing of these cylinders into wafers, techniques have been developed for producing silicon wafers or ribbons directly.

The first type of technique, a “liquid-phase” technique, illustrated by the EFG (Edge-defined Film-fed Growth) process (1), the RAD (Ribbon Against Drop) process (2) and the RGS (Ribbon Growth on Substrate) process (3) uses a liquid silicon bath.

In the EFG process, the liquid silicon rises in a capillary pipe and comes into contact with a seed that is then moved vertically. This technique makes it possible to produce large-sized octagonal tubes, with faces 125 mm wide (and 300 μm thick) from which the wafers are then cut.

In the RAD process, a sheet of flexible graphite passes vertically through the liquid silicon bath and emerges coated with silicon on both its faces. The thickness of the ribbons depends on the draw speed.

In the RGS process, a cold substrate in motion comes into contact with a liquid bath and emerges entraining a silicon film on one of its faces. Solidification starts from the substrate (solid/liquid front parallel to the plane of the ribbon) and generates a structure with small grains that is not optimal for photovoltaic application.

These processes generally make it possible to gain access to a silicon thickness ranging from 100 to 500 μm.

In parallel with this liquid-phase technology, there exists technology based on vapor-phase deposition illustrated by the CVD (4) and PVD (5) techniques. The films thus deposited are generally much thinner (maximum 20 μm) than those obtained via the liquid-phase processes. This vapor-phase technology makes it possible to work at high deposition rates and thus to ensure satisfactory productivity. However, the crystallographic structure thus obtained does not allow high energy conversion yields on account of its small crystal size.

It may also be envisioned to deposit as a liquid phase a mixture containing silicon powders in an organic solvent, to evaporate off the solvent and to sinter the powders using a hydrogenated argon plasma torch. In this case, very high levels of productivity may be achieved, and the technique has recently been used for the production of silicon for photovoltaic applications, but the crude sintering film does not allow high conversion yields.

Consequently, it appears that a certain number of techniques like, for example those illustrated by the CVD, PVD or plasma processes, are not entirely satisfactory especially with regard to the small size of the silicon crystals formed. Moreover, these processes are essentially directed toward proposing silicon films supported on a substrate and therefore do not concern the development of self-supporting silicon films, i.e. films not attached to a substrate material.

As regards the insufficiency of the size of the grains, observed for the films deposited by CVD, PVD or plasma, or even the RGS technique, it has already been proposed to perform recrystallizations by annealing supported silicon films at high temperature. One particularly advantageous process for annealing films is that of zone fusion, which consists in forming within the material under consideration a liquid bridge locally between two solid phases in a high-temperature zone, and in moving the material thus produced consecutively toward a cold zone. The technique has been known since the 1950s for the growth of massive monocrystals, especially made of silicon. It has recently been adapted to the crystallization of thin silicon films for photovoltaic applications (4). In the case of this process, zone-fusion annealing is used for recrystallizing a film a few micrometers thick that is to serve as an epitaxy substrate for the manufacture of cells as a thin film with processes based on vacuum deposition techniques. This advantageous technology for increasing the size of crystals is, however, considered in said document only for the formation of a silicon film supported on a substrate. Thus, the problem of detaching the silicon film thus formed from its substrate, which is another aspect considered according to the invention, is not addressed therein.

For obvious reasons, the ability of the silicon film to be detached easily or otherwise from its substrate is especially linked to the wettability manifested by the substrate in its regard.

It is known that in annealing processes involving a liquid phase and using non-wetting substrates, one solution for avoiding dewetting is to deposit a film of silica onto the silicon to be recrystallized (6). Unfortunately, this involves several additional process steps. To dispense with these additional steps, the use of materials that are naturally wetting or capable of forming a wetting substrate on contact with liquid silicon is generally preferred. For example, it is known that carbon on contact with liquid silicon leads to the formation of silicon carbide SiC, endowed with good wetting by liquid silicon.

Unfortunately, for the liquid-phase processes for preparing silicon films, the processes of solidification of the liquid silicon film and of detachment of the solid silicon film thus formed are closely linked, via the choice of temperature selected for the substrate. Thus, the thickness of the SiC film formed at the Si/substrate interface, which is a critical parameter for separability, is determined by the temperature of the substrate. It is known that a low substrate temperature limits, on the one hand, the diffusion of impurities, and, on the other hand, the formation of the SiC film, thus promoting detachment. Unfortunately, this low temperature induces in parallel a fine-grain silicon solidification microstructure that is unsuitable for photovoltaic applications. Furthermore, the advantages and drawbacks become inverted for high substrate temperatures.

Consequently, the technologies currently available cannot afford access quickly and simply to silicon films that are, firstly, self-supporting, i.e. free of a support substrate, and, secondly, endowed with a coarse-grain crystallographic structure, i.e. a structure in which the grain size is at least greater than 1 mm.

The present invention is precisely directed toward proposing a process that satisfies the abovementioned requirements.

In particular, the present invention is directed toward proposing a simplified, inexpensive process that is useful for affording access to silicon thin films, especially self-supporting silicon ribbons or wafers.

The present invention is also directed toward proposing a process for affording access directly to self-supporting silicon thin films having a coarse-grain crystallographic structure.

An object of the present invention is also to propose a process for manufacturing self-supporting silicon thin film(s) for simultaneously achieving coarse-grain silicon recrystallization and detachment of said silicon thin film thus formed from its original substrate.

More precisely, the present invention relates to a process for preparing a self-supporting crystallized silicon thin film, said process comprising at least the steps consisting in:
(1) having a wafer of material formed from at least three different superposed films, namely a substrate film, a surface silicon film and a carbon-based sacrificial film intercalated between the substrate film and toe surface film,
(2) heating at least one zone of the surface film of said wafer so as to melt the silicon present at the surface of said zone and to form an SiC film, adjacent to the film of molten silicon, by reacting the molten silicon with the carbon forming said sacrificial film,
(3) solidifying by cooling said molten silicon zone in step (2), and
(4) recovering the expected silicon thin film by spontaneous detachment of the SiC film from said substrate film.

The solidification step (3) is advantageously performed under conditions that are favorable to the formation of silicon crystals greater than 1 mm in size.

Advantageously, steps (2), (3) and (4) may be performed continuously.

According to one embodiment variant, the process also includes a step (5) comprising the removal of the SiC film contiguous to the expected silicon thin film.

According to another embodiment variant, the face of the substrate that is contiguous with the sacrificial film may have a relief. The process according to the invention then allows the replication of this relief on the formed silicon thin film, and thus the production of a textured silicon thin film.

According to yet another embodiment variant, the solidification or crystallization performed in step (3) may be initiated by seeding, i.e. by bringing the molten zone into contact with at least one external silicon crystal.

The presence of a film of a carbon-based material at the interface of the film of silicon to be recrystallized and of its substrate and the cooling of the molten silicon under the conditions required according to the invention give the silicon film thus obtained a crystallographic structure that is advantageous for a photovoltaic application and a good ability to be detached from its substrate.

Advantageously, in the context of the present invention, the two expected qualities, namely the production of a silicon film having a coarse-grain crystallographic structure and easy separation of said silicon film from its original substrate, are not acquired at each other's expense.

According to another of its aspects, the invention relates to the use of the process as described previously for preparing self-supporting silicon ribbons whose crystallographic structure has a grain size of greater than 1 mm.

Finally, a subject of the present invention is also the silicon ribbons obtained according to this process, which are especially self-supporting, whose crystallographic structure has a grain size of greater than 1 mm.

For the purposes of the invention, the term “self-supporting” means that the coarse-grain silicon film formed according to the claimed process is not solidly attached by adhesion to a solid substrate.

Wafer of Material

a) Carbon-Based Film

In order not to contaminate the silicon, the carbon chosen is as pure as possible and thus advantageously has a purity of greater than 99%, or even 99.9%.

The thickness of this carbon film may range from 10 nm to 2 μm and preferentially from 20 nm to 200 nm.

This film must be leaktight to silicon and must thus be free of open porosities, to prevent infiltration of the liquid silicon.

This carbon film may be produced according to standard techniques that are within the competence of a person skilled in the art. For example, this carbon film may be formed at the surface of one face of the substrate by pyrolysis of a gaseous or liquid precursor or deposited via a liquid route with evaporation of the solvent.

As emerges from the foregoing, the carbon film, at the interface of the substrate film and of the film of silicon to be recrystallized, is intended to be totally transformed by contact with the liquid silicon, into an SiC film, which the present invention is precisely directed toward exploiting in several respects.

Firstly, by blocking the diffusion of metallic elements that may be present in the substrate film, this SiC film chemically protects the film of liquid silicon.

Moreover, since the Si/SiC interface is energetically strong, good wetting of the SiC with the liquid Si, and thus morphological stability of the liquid silicon film, is thus ensured. Good wetting of this SiC film with silicon is also favorable to the replication of a substrate texture, if any, which is advantageous for trapping light in the cells and thus makes it possible to avoid the use of an additional step of chemical attack on the solidified ribbon, to create the relief.

Finally, since the silicon carbide film/substrate interface is mechanically weak, the thermomechanical constraints produced during cooling bring about spontaneous detachment by adhesive rupture, i.e. without cracking or deformation of the silicon and/or of the substrate.

b) Substrate Film

As regards the material forming the substrate, it may be of diverse nature.

The substrate materials that are more particularly suitable for use in the invention are of ceramic type, for example alumina or silicon nitride and more particularly materials that are poor heat conductors, like alumina.

This substrate material is advantageously in the form of a wafer or a ribbon, and especially a ribbon ranging from 5 to 20 cm in width and ranging from 500 μm to 10 mm and preferentially from 1 mm to 5 mm in thickness.

c) Silicon Film

As regards the silicon film, it generally has a “fine-grain” crystallographic structure, which it is precisely sought to increase via the process according to the invention.

This fine-grain crystallography generally has a size of less than 100 μm and especially less than 10 μm.

This silicon film may be formed via any standard process. It may especially be formed by CVD, PVD or powder deposition, or alternatively via the RGS technique, at the surface of the carbon film.

Its thickness may range from 10 μm to 500 μm and especially from 100 μm to 200 μm.

Other characteristics and advantages of the invention will emerge more clearly on reading the description that follows, which is given as a nonlimiting illustration with reference to the attached figures, in which:

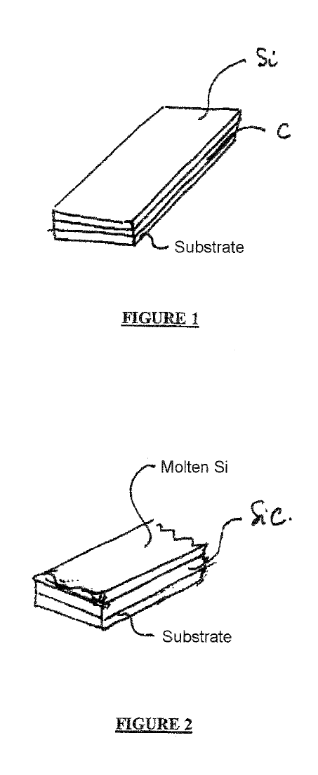

FIG. 1 is a schematic cross section of a wafer of material that is to be treated according to the invention,

FIG. 2 is a schematic cross section of a wafer obtained during step (2),

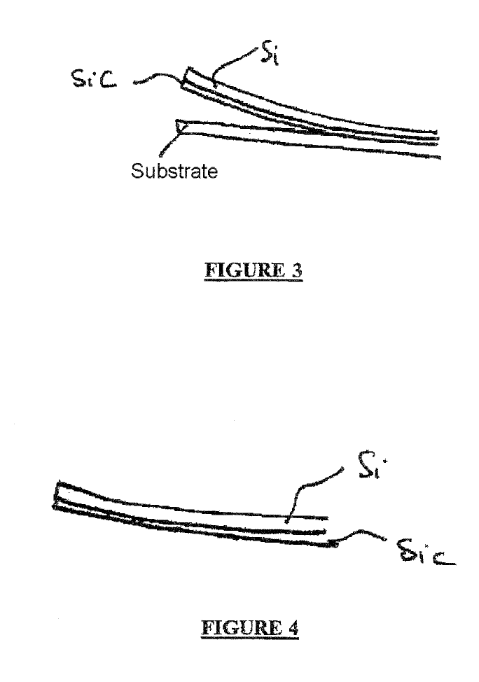

FIG. 3 illustrates the step of detaching the Si/SiC thin film from the substrate film,

FIG. 4 is a schematic cross section of a silicon/SiC thin film obtained according to the process of the invention,

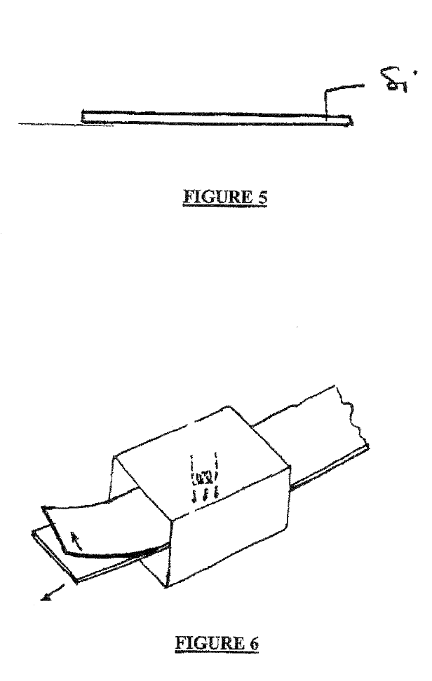

FIG. 5 shows the silicon thin film obtained after removing the SiC film, and

FIG. 6 illustrates the longitudinal movement of a wafer during its treatment according to the invention inside a heating chamber and the recovery at the end of this chamber of an Si/SiC thin film by spontaneous detachment of the SiC film from the substrate film.

It should be noted that, for reasons of clarity, the various films of material of the structures visible in the figures are not drawn to scale; the dimensions of certain parts are greatly exaggerated.

### DETAILED DESCRIPTION OF ONE EMBODIMENT OF THE INVENTION

In accordance with step (2), at least one zone of the surface film of a wafer of material to be recrystallized, especially as defined above, is brought locally to a temperature above the melting point of silicon, i.e. a temperature above 1410° C.

This temperature is, moreover, advantageously less than 1700° C., especially less than 1550° C., or even less than 1500° C.

According to the chosen temperature, the size of the molten zone may range from 5 mm to 5 cm and especially from 5 mm to 2 cm.

As stated previously, this step (2) makes it possible, firstly, to melt the silicon in the zone exposed to local heating, and, secondly, to transform the carbon, contiguous with this zone, into silicon carbide SiC.

The zone thus treated is then exposed to conditions favorable to its recrystallization to a grain size of greater than 1 mm.

These conditions in particular require cooling of the molten zone below the melting point.

This cooling of the molten zone may be progressive with a cooling rate of 10° C. to 1000° C./hour and advantageously from 50° C. to 300° C./hour.

Advantageously, this cooling that is favorable to the recrystallization of the molten silicon is performed under conditions such that the heat exchanges in the thickness of the molten zone formed by the Si/SiC/substrate materials are significantly reduced.

This is obtained by controlling the temperature on either side of the thickness of the film (for example heating on each of the faces of the film).

To this end, the heating means are advantageously located on either side of the wafer.

In other words, a temperature gradient is, beneficially, provided essentially in the longitudinal direction on the substrate film rather than in the direction of its thickness.

To do this, the substrate may be advantageously exposed for its cooling, i.e. during the cooling step (3), or even as early as step (2), to a temperature that has a temperature difference with the crystallization temperature of between 0 and 20° C.

As stated previously, steps (2), (3) and (4) may be performed continuously.

Thus, steps (2) and (3) may be performed in a heating chamber into which is introduced said wafer that is to be treated according to the invention.

This chamber is capable precisely of affording, firstly, the local heating required for step (2), and, secondly, the thermal energy needed to heat the substrate, preferably with a temperature gradient that is exerted essentially in the longitudinal direction of the substrate and that proves most particularly advantageous for affording the expected silicon recrystallization size according to the invention.

To favor this mode of heat transmission, substrates that are poor heat conductors, for example alumina, may also preferentially be used.

Furthermore, the wafer of material and said chamber are advantageously made to move relative to each other so that any molten zone in step (2) is consecutively moved toward the zone of the chamber that is favorable for its recrystallization by cooling.

More particularly, it is the wafer that is moved through the chamber.

As regards the local heating device, required for performing step (2), it is advantageously fitted into the chamber so as to apply to only one zone of said wafer of material to be treated.

This local heat treatment may be performed via any conventional means suitable for localized heating. Induction heating methods are most particularly suitable for use in the invention. However, heat treatments of resistive, infrared, laser, mirror oven, etc. type may also be considered, or any combination of these treatments.

As regards the cooling, it may be advantageous at the start of this cooling to bring the molten zone into contact with a silicon seed crystal, especially by bringing this molten zone into contact with a microcrystalline wafer. This recrystallization technique clearly falls within the competence of a person skilled in the art.

During cooling, the Si/SiC two-film wafer spontaneously detaches from the substrate film, i.e. without it being necessary to apply a mechanical constraint in order to detach it.

After step (4) of the process, a recrystallized silicon film free of solid substrate is thus obtained. It is, however, coated on one of its faces with a silicon carbide film generally of submicron thickness.

This silicon carbide film may be consecutively removed according to the usual techniques and generally by means of a chemical treatment.

The invention will now be described by means of the example that follows, which is, of course, given as a nonlimiting illustration of the invention.

### EXAMPLE

An alumina wafer (length 50 cm, width 10 cm, thickness 5 mm) onto which has first been deposited a film of about 100 nm of pyrocarbon is coated with a film of sintered powders. The assembly is placed on a conveyor belt passing through a high-temperature chamber. The substrate is heated at the bottom by induction, an IR heating lamp device also being used at the top to provide additional heating. A maximum temperature of 1500° C. is thus reached on the sample (measurement by pyrometry), which leads to the formation of a centimeter-sized liquid silicon zone. Drawing is initiated by switching on the conveyor belt at a speed of about 50 μm/sec. During the cooling, the ribbon becomes detached from the ceramic substrate. After returning to room temperature, the submicron-sized SiC film adhering to the silicon is removed chemically (nitric acid-hydrofluoric acid mixture).

Cited Documents

(1) B. Mackintosch et al., J. Crystal Growth, 287 (2006) 428-432,

(2) C. Belouet, “Growth of silicon ribbons by the RAD process”, J. Crystal Growth, 82 (1987) 110-116,

(3) EP 165 449 A,

(4) S. Reber, A. Hurrle, A. Eyer, G. Wilke, “Crystalline silicon thin film solar cells—recent results at Fraunhofer ISE”, Solar Energy, 77 (2004) 865-875,

(5) M. Aoucher, G. Farhi, T. Mohammed-Brahim, J. Non-Crystalline Solids, 227-230 (1998) 958,

(6) T. Kieliba et al., “Crystalline silicon thin film solar cells on ZrSiO₄ ceramic substrates”, Solar Energy Materials & Solar Cells, 74 (2002) 261.

1. A process for preparing a self-supporting crystallized silicon thin film, said process comprising at least the steps consisting in:
(1) having a wafer of material formed from at least three different superposed films, namely a substrate film, a surface silicon film and a carbon-based sacrificial film intercalated between the substrate film and the surface film,
(2) heating at least one zone of said wafer so as to melt the silicon present at the surface of said zone and to form an SiC film, adjacent to the film of molten silicon, by reacting said molten silicon with the carbon forming said sacrificial film,
(3) solidifying by cooling said molten silicon zone in step (2), and
(4) recovering the expected silicon thin film by spontaneous detachment of the SiC film from said substrate film.

2. The process as claimed in claim 1, wherein the silicon thin film thus formed has a grain size of greater than 1 mm.

3. The process as claimed in claim 1, further comprising a step (5) of removing the SiC film.

4. The process as claimed in claim 1, wherein steps (2), (3) and (4) are performed continuously.

5. The process as claimed in claim 1, wherein the crystallization performed in step (3) is initiated by bringing the molten zone into contact with at least one silicon crystal.

6. The process as claimed in claim 1, wherein the face of the substrate that is contiguous with the sacrificial film has a relief.

7. The process as claimed in claim 1, wherein the thickness of the carbon film is less than 2 μm.

8. The process as claimed in claim 1, wherein the substrate film is formed from a material of ceramic type.

9. The process as claimed in claim 1, wherein the zone heated in step (2) is at a temperature ranging from 1410° C. to 1700° C.

10. The process as claimed in claim 1, wherein the heating means are located on either side of the thickness of the wafer.

11. The process as claimed in claim 1, wherein the substrate is exposed for its cooling to a temperature that has a temperature difference with the crystallization temperature of between 0 and 20° C.

12. The process as claimed in claim 1, wherein steps (2) and (3) are performed in a heating chamber equipped with a local heating device.

13. The process as claimed in claim 1, wherein the wafer of material and said chamber are made to move relative to each other so as to move the molten zone in step (2) toward a zone of said chamber that is favorable to its cooling.

14. (canceled)

15. A self-supporting silicon ribbon, whose crystallographic structure has a grain size of greater than 1 mm, obtained by a process comprising:
(1) having a wafer of material formed from at least three different superposed films, namely a substrate film, a surface silicon film and a carbon-based sacrificial film intercalated between the substrate film and the surface film,
(2) heating at least one zone of said wafer so as to melt the silicon present at the surface of said zone and to form an SiC film, adjacent to the film of molten silicon, by reacting said molten silicon with carbon forming said sacrificial film,
(3) solidifying by cooling said molten silicon zone in step (2), and
(4) recovering the expected silicon thin film by spontaneous detachment of the SiC film from said substrate film.

16. The process as claimed in claim 8, wherein said material of ceramic type is a poor heat conductor.

17. The process as claimed in claim 1, wherein the zone heated in step (2) is at a temperature less than 1550° C.

18. The process as claimed in claim 1, wherein the zone heated in step (2) is at a temperature less than 1550° C.

19. A process for preparing self-supporting silicon ribbons whose crystallographic structure has a grain size of greater than 1 mm using a process comprising:
(1) having a wafer of material formed from at least three different superposed films, namely substrate film, a surface silicon film and a carbon-based sacrificial film intercalated between the substrate film and the surface film,
(2) heating at least one zone of said wafer so as to melt the silicon present at the surface of said zone and to form an SiC film, adjacent to the film of molten silicon, by reacting said molten silicon with carbon forming said sacrificial film, silicon with carbon forming said sacrificial film,
(3) solidifying by cooling said molten silicon zone in step (2), and
(4) recovering the expected silicon thin film by spontaneous detachment of the SiC film from said substrate film.
